(19) United States
(12) Patent Application Publication
(10) Pub. No.: US 2015/0204933 A1
(43) Pub. Date: Jul. 23, 2015

(54) DIFFERENTIAL SIGNAL TRANSMISSION SYSTEM FOR DETECTING STATE OF TRANSMISSION LINES

(71) Applicant: Samsung Electronics Co., Ltd., Gyeonggi-do (KR)

(72) Inventor: Philjae Jeon, Gyeonggi-do (KR)

(73) Assignee: Samsung Electronics Co., Ltd.

(21) Appl. No.: 14/519,940

(22) Filed: Oct. 21, 2014

(30) Foreign Application Priority Data
Jan. 21, 2014 (KR) 10-2014-0007342

(51) Int. Cl. G01R 31/02

(52) U.S. Cl. CPC G01R 31/021

(57) ABSTRACT

A differential signal transmission system and method for detecting an open state or the short state therein are provided. The differential signal transmission system includes first and second transmission lines; a termination resistance unit between a first node on the first transmission line and a second node on the second transmission line; a first pass unit that controls a first current flowing between a third node connected to a first driving voltage and the first node based on a first control signal; a second pass unit that controls a second current flowing between the second node and a fourth node connected to a second driving voltage based on a second control signal; a measurement unit that measures a voltage level of the first node or the second node to detect an open or short state of at least one of the first transmission line and the second transmission line.

### PRIORITY

The present application claims priority under 35 U.S.C. §119 to Korean Patent Application No. 10-2014-0007342, which was filed in the Korean Intellectual Property Office on Jan. 21, 2014, the entire content of which is incorporated herein by reference.

### BACKGROUND

1. Field of the Invention

The present invention relates generally to a differential signal transmission system, and more particularly, to a differential signal transmission system capable of detecting an open or short state of transmission lines for a differential signal.

2. Description of the Related Art

Transmission of a differential signal has been used for improved signal transmission. Generally, the differential signal is formed of two signals that have a phase difference of 180°. A signal receiving device recovers a single-level signal, which a signal transmitting device intends to send, based on a level difference between two signals constituting the differential signal. The two signals may be distorted during transmission due to a variety of causes. However, each of the two signals transmitted via adjacent lines may be distorted by almost the same amount. Although the two signals are distorted, a level difference between the two signals is almost constant. Thus, it is still possible to recover a single-level signal that a signal transmitting device intends to send.

However, when the signal transmitting device transmits a single-level signal instead of the differential signal from the beginning, the signal receiving device receives an incorrect signal when the single-level signal is distorted. That is, differential signaling improves signal transmission as compared with a method of transmitting a single-level signal.

Differential signal transmission lines, i.e., lines for a transferring differential signals, may have a fault, such as an open state or a short state, due to a variety of causes (e.g., an error of manufacturing process). For example, the differential signal transmission lines may be shorted, or one of lines may be opened. In this case, it is difficult to transmit a signal correctly. However, while a faulty state of the differential signal transmission lines should be detected, an open state or a short state of the differential signal transmission lines is not easily detected with the naked eye.

Typically, an open state or a short state of differential signal transmission lines is detected through manual operations, such as: (1) measuring a voltage level on points of the differential signal transmission lines, or (2) determining whether a signal is normally transmitted after a cable is replaced. However, such manual operations generally involve a lot of time and manpower.

### SUMMARY

The present invention has been made to address at least the above problems and/or disadvantages and to provide at least the advantages described below.

Accordingly, an aspect of the present invention is to provide a differential signal transmission system capable of detecting an open state or a short state of transmission lines for a differential signal.

In accordance with an aspect of the present invention, a differential signal transmission system is provided, which includes first and second transmission lines configured to transmit a differential signal; a termination resistance unit connected between a first node on the first transmission line and a second node on the second transmission line; a first pass unit configured to control a first current flowing between a third node connected to a first driving voltage and a the first node based on a first control signal; a second pass unit configured to control a second current flowing between the second node and a fourth node connected to a second driving voltage based on a second control signal, a level of the second driving voltage being lower than a level of the first driving voltage; a measurement unit configured to measure a voltage level of at least one of the first and second nodes to detect an open or short state of at least one of the first and second transmission lines; and a control unit configured to control at least one of a transmission of the differential signal, a connection of the termination resistance unit, and each of values of the first and second control signals.

In accordance with another aspect of the present invention, a differential signal transmission system is provided, which includes a plurality of differential signal line pairs, each of the plurality of differential signal line pairs having a positive channel and a negative channel configured to transfer a differential signal; a plurality of termination resistance units, each of the plurality of termination resistance units connected between a positive node on the positive channel and a negative node on the negative channel; a plurality of positive pass units, each of the plurality of positive pass units configured to control a positive current flowing between a first node connected to a first driving voltage and the positive node based on a positive control signal; a plurality of negative pass units, each of the plurality of negative pass units configured to control a negative current flowing between the negative node and a second node connected to a second driving voltage based on a negative control signal, a level of the second driving voltage being lower than a level of the first driving voltage; a measurement unit configured to measure a voltage level of at least one of the positive node and the negative node to detect an open or short state of each of the plurality of differential signal line pairs; and a control unit configured to control at least one of a transfer of the differential signal, a connection of each of the plurality of termination resistance unit, a value of the positive control signal, and a value of the negative control signal.

In accordance with another aspect of the present invention, a method of detecting an open state or a short state of at least one of a first transmission line and a second transmission line of differential signal transmission system is provided, which includes controlling a first current flowing between a third node connected to a first driving voltage and a first node on the first transmission line based on a first control signal; controlling a second current flowing between a second node on the second transmission line and a fourth node connected to a second driving voltage based on a second control signal, wherein a level of the second driving voltage is lower than a level of the first driving voltage; measuring a voltage level of at least one of the first node and the second node; and detecting the open or short state of the at least one of the first transmission line and the second transmission line, based on the measured voltage level.

### BRIEF DESCRIPTION OF THE DRAWINGS

The above and other aspects, features, and advantages of certain embodiments of the present invention will become apparent from the following detailed description when taken in conjunction with the accompanying drawings, in which:

FIG. 1 schematically illustrates a differential signal transmission system according to an embodiment of the present invention;

FIG. 2 schematically illustrates a differential signal transmission system according to an embodiment of the present invention;

FIGS. 3 and 4 illustrate an operation of detecting whether one of differential signal transmission lines is shorted with the other line, according to an embodiment of the present invention;

FIG. 5 is a flow chart illustrating a method of detecting whether one of differential signal transmission lines is shorted with the other line, according to an embodiment of the present invention;

FIGS. 6 and 7 illustrate an operation of detecting whether one of differential signal transmission lines is shorted with a ground node, according to an embodiment of the present invention;

FIG. 8 is a flow chart illustrating a method of detecting whether one of differential signal transmission lines is shorted with a ground node, according to an embodiment of the present invention;

FIGS. 9 and 10 illustrate an operation of detecting whether one of differential signal transmission lines is opened, according to an embodiment of the present invention;

FIG. 11 is a flow chart illustrating a method of detecting whether one of differential signal transmission lines is opened, according to an embodiment of the present invention;

FIG. 12 schematically illustrates a differential signal transmission system according to an embodiment of the present invention; and

FIG. 13 illustrates a display device including a differential signal interface according to an embodiment of the present invention.

### DETAILED DESCRIPTION OF EMBODIMENTS OF THE INVENTION

Various embodiments of the present invention will be described in detail below with reference to the accompanying drawings. However, the inventive concepts therein may be embodied in different forms, and should not be construed as being limited only to the illustrated embodiments. Rather, these embodiments are provided as examples so that this disclosure will be thorough and complete, and will fully convey the concept of the present invention to those skilled in the art. Accordingly, known processes, elements, and techniques are not described with respect to some of the embodiments.

Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first” or “second” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be referred to as a second element, component, region, layer or section without departing from the teachings of the inventive concept.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

Unless otherwise defined, all terms (including technical and scientific terms) used herein have the same meaning as commonly understood by one of ordinary skill in the art to which this present invention belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Below, it is assumed that a Low-Voltage Differential Signaling (LVDS) system is used as a differential signal transmission system. However, the present invention is not limited thereto. For example, the embodiments of the present invention are also applicable to Bus-LVDS (B-LVDS), Multipoint-LVDS (M-LVDS), and mini-LVDS systems, which have a modified configuration of the LVDS system. Further, the embodiments of the present invention are applicable to systems using Low-Voltage Positive/Pseudo Emitter-Coupled Logic (LVPECL), Current-Mode Logic (CML), and Voltage-Mode Logic (VML) interfaces for transmission of a differential signal and systems using Advanced Intra-Panel Interface (AIPI) or High Definition Multimedia Interface (HDMI).

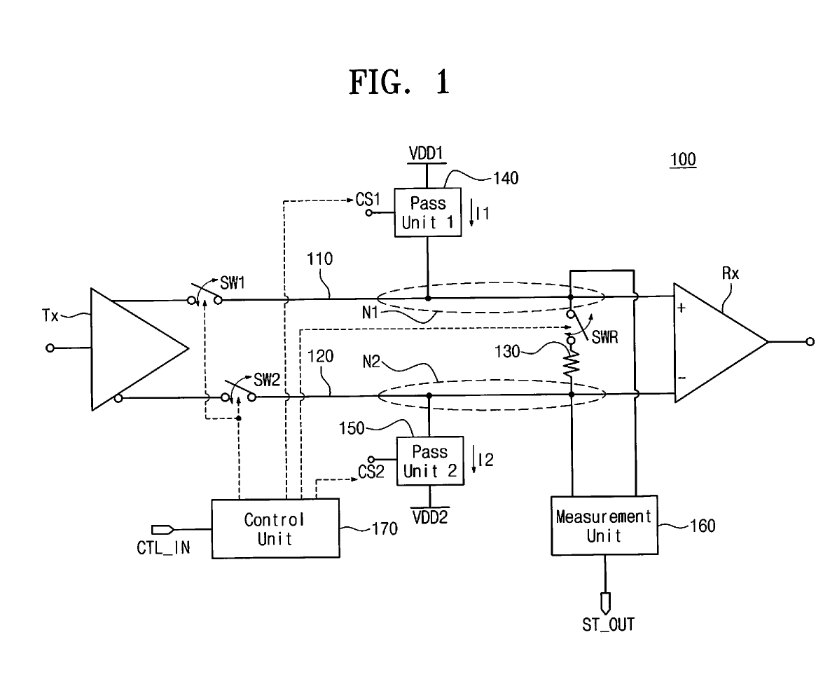

FIG. 1 schematically illustrates a differential signal transmission system according to an embodiment of the present invention.

Referring to FIG. 1, the differential signal transmission system 100 includes a first transmission line 110, a second transmission line 120, a termination resistance unit 130, a first pass unit 140, a second pass unit 150, a measurement unit 160, and a control unit 170.

The first transmission line 110 and the second transmission line 120 transmit a differential signal, which is provided from a transmitter Tx, to a receiver Rx. For example, a signal flowing along the first transmission line 110 and a signal flowing along the second transmission line 120 may have a phase difference of 180°.

The termination resistance unit 130 is connected between the first transmission line 110 and the second transmission line 120. In particular, the termination resistance unit 130 is connected between a first node N1 on the first transmission line 110 and a second node N2 on the second transmission line 120. The termination resistance unit 130 prevents the differential signal from being reflected from the receiver Rx, thereby preventing lowering of signal quality. The termination resistance unit 130 may be disposed on a chip together with the receiver Rx.

Although the termination resistance unit 130 is illustrated as a resistor in FIG. 1, the embodiment of the invention is not limited thereto, and the termination resistance unit 130 may be implemented with another element or structure having a resistance component.

One terminal of the first pass unit 140 is connected to a third node at which a first driving voltage VDD1 is applied. The other terminal of the first pass unit 140 is connected to the first transmission line 110, i.e., to the first node N1. The first pass unit 140 operates according to a first control signal CS1. A first current I1 flowing between one terminal and the other terminal of the first pass unit 140 is controlled based on the first control signal CS1.

One terminal of the second pass unit 150 is connected to the second transmission line 120, i.e., to the second node N2. The other terminal of the second pass unit 150 is connected to a fourth node at which a second driving voltage VDD2 is applied. A level of the second driving voltage VDD2 may be lower than that of the first driving voltage VDD1. The second pass unit 150 operates according to a second control signal CS2. A second current I2 flowing between one terminal and the other terminal of the second pass unit 150 is controlled based on the second control signal CS2.

The measurement unit 160 is connected to the first node N1 and the second node N2. The measurement unit 160 measures a voltage level of at least one of the first node N1 and the second node N2. A faulty state (e.g., an open state or a short state) of at least one of the first transmission line 110 and the second transmission line 120 is detected according to the measurement result of the measurement unit 160. The measurement result of the measurement unit 160 is outputted through a state output terminal ST_OUT.

The control unit 170 directly or indirectly controls components or signals of the differential signal transmission system 100. For example, the control unit 170 controls a transfer of the differential signal. The control unit 170 controls connections between the transmitter Tx and each of the first transmission line 110 and the second transmission line 120 to control the transfer of the differential signal. For example, the control unit 170 controls a first switch SW1 for connecting the transmitter Tx and the first transmission line 110. Further, the control unit 170 controls a second switch SW2 for connecting the transmitter Tx and second transmission line 120. A configuration of the first and second switches SW1 and SW2 is an example for better understanding of the embodiment of the present invention and does not limit the inventive concept thereof. That is, the connections between the transmitter Tx and each of the first transmission line 110 and the second transmission line 120 may be controlled according to another configuration or method different from that described above.

The control unit 170 controls a connection between the termination resistance unit 130 and at least one of the first and second nodes N1 and N2 to control a current flow into the termination resistance unit 130. For example, the control unit 170 controls a switch SWR for connecting the first node N1 and the termination resistance unit 130. A configuration of the switch SWR is an example for better understanding of the embodiment of the present invention and does not limit the inventive concept thereof. That is, a connection between the termination resistance unit 130 and at least one of the first and second nodes N1 and N2 may be controlled according to another configuration or method different from that described above.

The control unit 170 controls a value of at least one of the first and second control signals CS1 and CS2. For example, when the first and second control signals CS1 and CS2 take the form of a voltage, the control unit 170 may control a voltage source that generates the first and second control signals CS1 and CS2. As the values of the first and second control signals CS1 and CS2 are controlled, flow of the first and second current I1 and I2 may be controlled, respectively. Further, as the values of the first and second control signals CS1 and CS2 are controlled, the first and second currents I1 and I2 may be controlled, respectively.

The above-described functions of the control unit 170 are exemplary. That is, the control unit 170 may also be configured to control other components or signals of the differential signal transmission system 100. The control unit 170 controls a component or signal of the differential signal transmission system 100 to detect a faulty state of at least one of the first transmission line 110 and the second transmission line 120. The control unit 170 may operate according to a command, which is provided from the inside or outside of the differential signal transmission system 100 through a control input terminal CTL_IN, and/or control a component or signal of the differential signal transmission system 100, directly or indirectly, based on an embedded instruction.

Although the first pass unit 140, the second pass unit 150, the measurement unit 160, and the control unit 170 are disposed at an area different from an area where the transmitter Tx and the receiver Rx are disposed in FIG. 1, alternatively some or all of the first pass unit 140, the second pass unit 150, the measurement unit 160, and the control unit 170 may be disposed on one or more chips together with one of the transmitter Tx and the receiver Rx. For example, the first pass unit 140, the second pass unit 150, and the measurement unit 160 may be disposed on a chip together with the receiver Rx, and the control unit 170 may be disposed on another chip with the transmitter Tx. That is, components of the differential signal transmission system 100 may be disposed by various manners as necessary or preferred.

The first driving voltage VDD1 may be a positive voltage having a level greater than a specific voltage level. For example, a voltage level approximate to a voltage level of the first driving voltage VDD1 may be defined as logic high. Further, the second driving voltage VDD2 may be a ground voltage, and a voltage level approximate to a voltage level of the second driving voltage VDD2 may be defined as logic low.

In FIG. 1, the first current I1 flows from one terminal of the first pass unit 140 to the other terminal thereof, and the second current I2 flows from one terminal of the second pass unit 150 to the other terminal thereof. Further, it is assumed that the first driving voltage VDD1 is a positive voltage having a level greater than a voltage level corresponding to logic high and the second driving voltage VDD2 is a ground voltage. However, the inventive concept is not limited thereto.

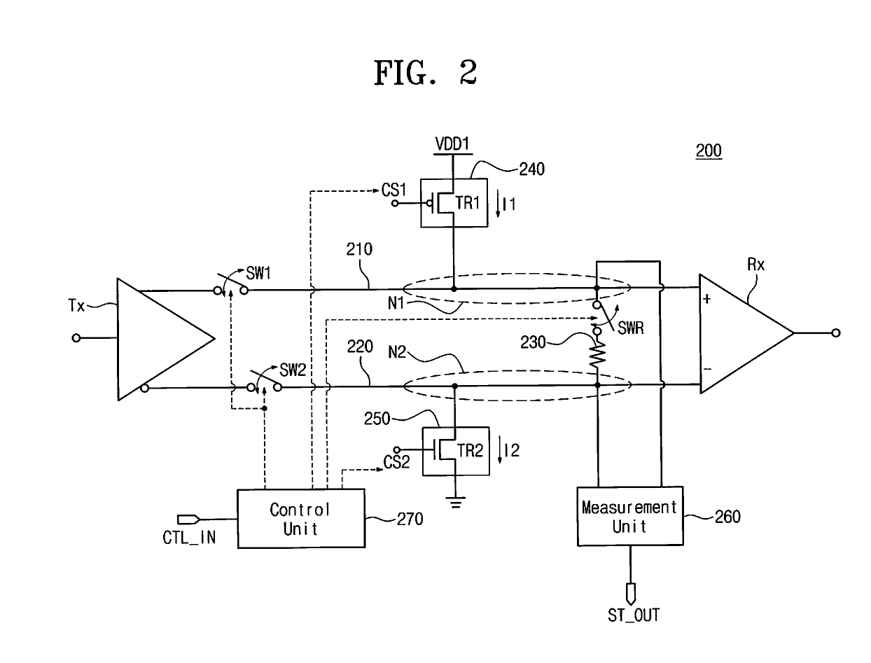

FIG. 2 schematically illustrates a differential signal transmission system according to another embodiment of the present invention.

Referring to FIG. 2, the differential signal transmission system 200 includes a first transmission line 210, a second transmission line 220, a termination resistance unit 230, a first pass unit 240, a second pass unit 250, a measurement unit 260, and a control unit 270. Because the configurations and functions of a first transmission line 110, a second transmission line 120, a termination resistance unit 130, a first pass unit 140, a second pass unit 150, a measurement unit 160, and a control unit 170 of a differential signal transmission system 100 as illustrated in FIG. 1 and described above are the same as those of the first transmission line 210, the second transmission line 220, the termination resistance unit 230, the first pass unit 240, the second pass unit 250, the measurement unit 260, and the control unit 270 illustrated in FIG. 2, a description repetitive description of these components is omitted.

The first pass unit 240 includes a P-channel Metal-Oxide Semiconductor (PMOS) transistor TR1, and the second pass unit 250 includes an N-channel Metal-Oxide Semiconductor (NMOS) transistor TR2. One terminal of the PMOS transistor TR1 is connected to a first driving voltage VDD1, and the other terminal thereof is connected to a first node N1. A first control signal CS1 is provided to a gate terminal of the PMOS transistor TR1. A first current I1, which flows between one terminal and the other terminal of the PMOS transistor TR1, is controlled based on the first control signal CS1.

One terminal of the NMOS transistor TR2 is connected to a second node N2, and the other terminal thereof is connected to a second driving voltage VDD2 (refer to FIG. 1). In FIG. 2, the second driving voltage VDD2 is a ground voltage. A second control signal CS2 is provided to a gate terminal of the NMOS transistor TR2. A second current I2, which flows between one terminal and the other terminal of the NMOS transistor TR2, is controlled based on the second control signal CS2.

The configurations of the first pass unit 240 and the second pass unit 250 illustrated in FIG. 2 are exemplary, and the first pass unit 240 and the second pass unit 250 may be implemented with elements or structures different from those described above.

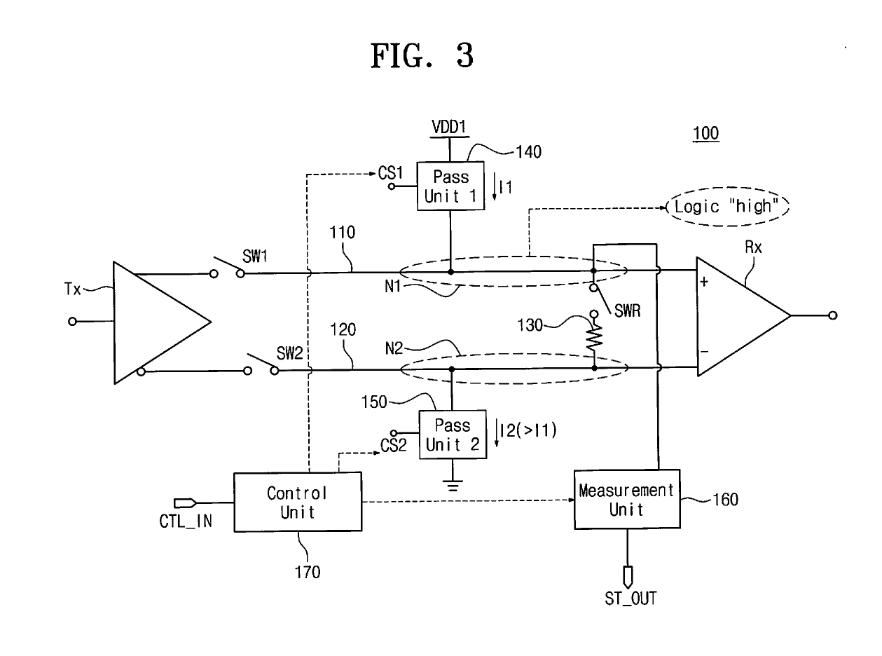

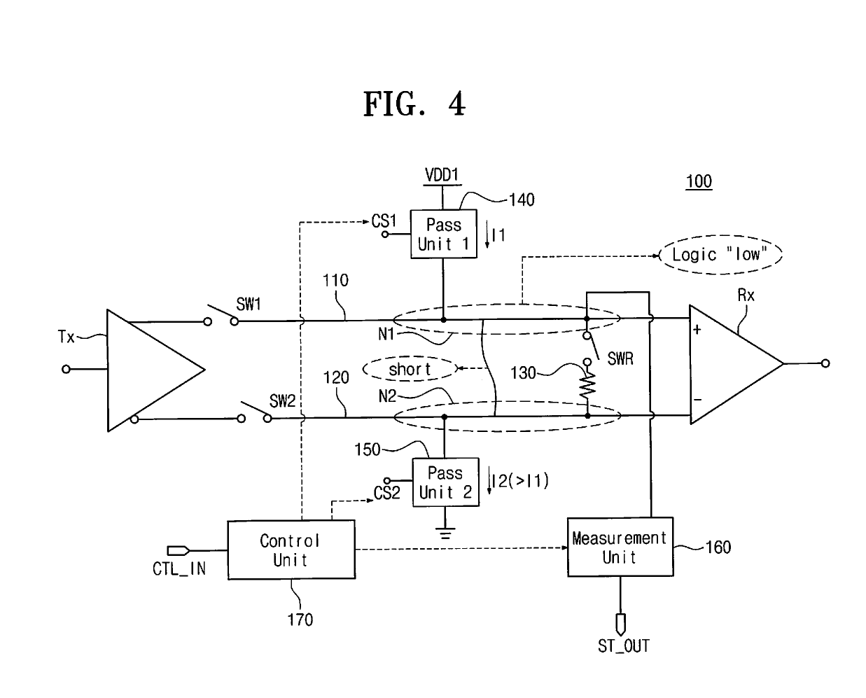

FIGS. 3 and 4 illustrate an operation of detecting whether one of differential signal transmission lines is shorted with the other line, according to an embodiment of the present invention. As described above, it is assumed that a first driving voltage VDD1 is a positive voltage having a level greater than a voltage level corresponding to logic high and a second driving voltage VDD2 is a ground voltage.

First, an operation of setting a condition for detecting whether a first transmission line 110 is shorted with a second transmission line 120 will be described.

Referring to FIG. 3, a control unit 170 controls first and second switches SW1 and SW2, such that a differential signal is not transmitted from a transmitter Tx. For example, the control unit 170 opens the first and second switches SW1 and SW2 to disconnect the first and second transmission lines 110 and 120 from the transmitter Tx. In this case, the transmitter Tx will have a high-impedance state (Hi-Z).

The control unit 170 controls a switch SWR, such that no current flows into a termination resistance unit 130. For example, the control unit 170 opens the switch SWR to disconnect the termination resistance unit 130 from a first node N1. In this case, no current flows into the termination resistance unit 130.

The control unit 170 controls values of first and second control signals CS1 and CS2, such that a first pass unit 140 and a second pass unit 150 are turned on. That is, the control unit 170 controls the first and second pass units 140 and 150, such that a first current I1 and a second current I2 flow. Further, the control unit 170 controls the values of the first and second control signals CS1 and CS2, such that the second current I2 is greater than the first current I1.

According to the above-described operation of the control unit 170, a condition is set up for detecting whether the first transmission line 110 is shorted with the second transmission line 120. Thereafter, the control unit 170 controls the measurement unit 160 to measure a voltage level of the first node N1. Whether the first transmission line 110 is shorted with the second transmission line 120 may be detected, based on a result of measuring the voltage level of the first node N1.

A case in which the first transmission line 110 is not shorted with the second transmission line 120 will be described with reference to FIG. 3.

Referring to FIG. 3, the first current I1 flows between one terminal and the other terminal of the first pass unit 140 according to the first control signal CS1, and the second current I2 flows between one terminal and the other terminal of the second pass unit 150 according to the second control signal CS2. However, a path allowing the first current I1 to flow is not formed, because the switch SWR is opened and the first transmission line 110 is not shorted with the second transmission line 120. Thus, the voltage of the first node N1 measured by the measurement unit 160 will be approximate to the first driving voltage VDD1. As described above, a level of the first driving voltage VDD1 is greater than a voltage level corresponding to logic high; hence, the voltage of the first node N1 measured by the measurement unit 160 may correspond to logic high. Thus, when the first transmission line 110 is not shorted with the second transmission line 120, the first node N1 will be measured to have a voltage level corresponding to logic high. That is, if the first node N1 has a voltage level corresponding to logic high, the measurement unit 160 can detect that the first transmission line 110 is not shorted with the second transmission line 120.

A case in which the first transmission line 110 is shorted with the second transmission line 120 will be described with reference to FIG. 4.

Referring to FIG. 4, when the first transmission line 110 is shorted with the second transmission line 120, the first node N1 will be measured to have a voltage level approximate to a ground voltage, because the second current I2 is greater than the first current I1 (i.e., a driving power of the second pass unit 150 is greater than that of the first pass unit 140). That is, the first node N1 will be measured to have a voltage level corresponding to logic low during a short.

As a result, when the first transmission line 110 is shorted with the second transmission line 120, the first node N1 will be measured to have a voltage level corresponding to logic low. That is, if the first node N1 has a voltage level corresponding to logic low, the measurement unit 160 can detect that the first transmission line 110 is shorted with the second transmission line 120.

In FIGS. 3 and 4, a driving power of the second pass unit 150 is greater than that of the first pass unit 140, i.e., the second current I2 is greater than the first current I1. If the second current I2 is insufficient, a voltage level of the first node N1 measured when the first transmission line 110 is shorted with the second transmission line 120 may not correspond to logic low. However, the excessive second current I2 may cause an unstable operation and high power consumption of the differential signal transmission system 100. In accordance with an embodiment of the present invention, the control unit 170 adjusts each of values of the first and second control signals CS1 and CS2 such that the second current I2 is four times greater than the first current I1.

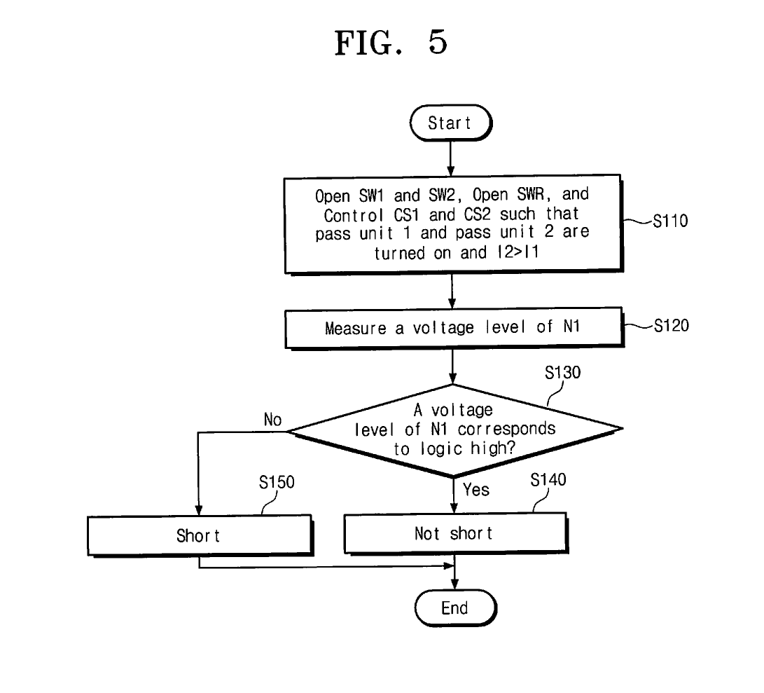

FIG. 5 is a flow chart illustrating a method of detecting whether one of differential signal transmission lines is shorted with the other line, according to an embodiment of the present invention. Specifically, FIG. 5 illustrates an operation of detecting whether a first transmission line 110 is shorted with a second transmission line 120 in a differential signal transmission system as illustrated in FIG. 3 or 4.

Referring to FIG. 5, in step S110, first and second switches SW1, SW2, and SWR are opened, and each of values of first and second control signals CS1 and CS2 is controlled such that a first pass unit 140 and a second pass unit 150 are turned on and such that a first current I1 and a second current I2, which is greater than the first current I1, flow. Basically, a condition is set for detecting whether a first transmission line 110 is shorted with a second transmission line 120 in step S110.

In step S120, a voltage level of a first node N1 is measured. Whether the first transmission line 110 is shorted with the second transmission line 120 is determined based on a result of measuring the voltage level of the first node N1.

In step S130, if the voltage level of the first node N1 corresponds to logic high, it is determined that the first transmission line 110 is not shorted with the second transmission line 120 in step S140. However, if the voltage level of the first node N1 does not correspond to logic high (corresponds to logic low) in step S130, it is determined that the first transmission line 110 is shorted with the second transmission line 120 in step S150.

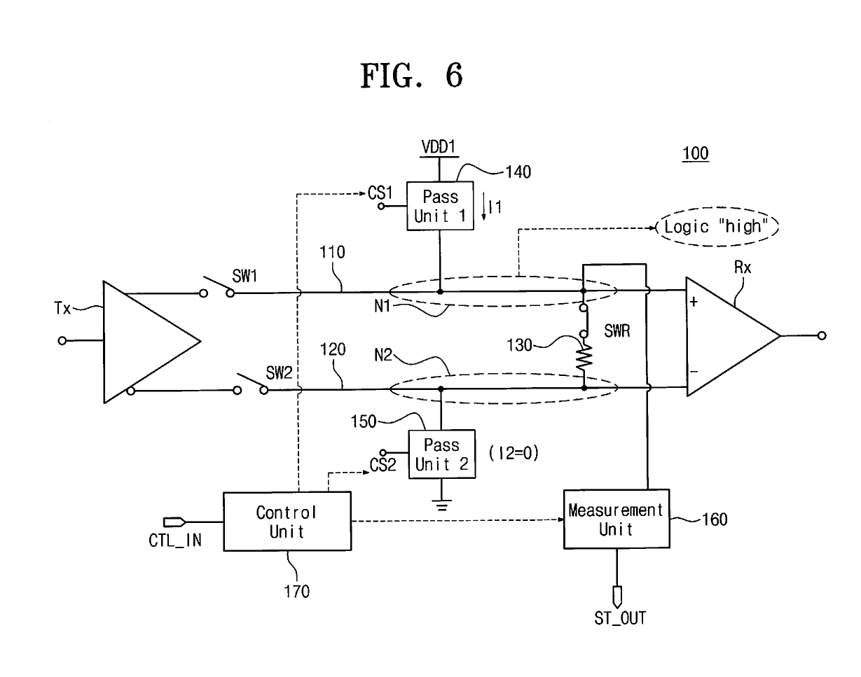

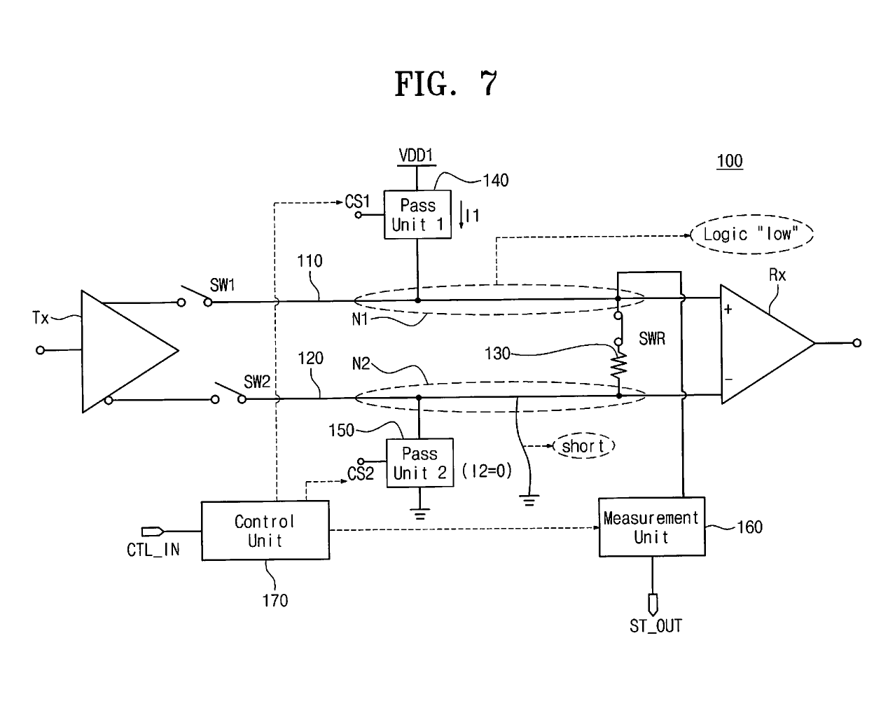

FIGS. 6 and 7 illustrate an operation of detecting whether one of differential signal transmission lines is shorted with a ground node, according to an embodiment of the present invention. As described above, it is assumed that a first driving voltage VDD1 is a positive voltage having a level greater than a voltage level corresponding to logic high and a second driving voltage VDD2 is a ground voltage.

First, an operation of setting a condition for detecting whether at least one of a first transmission line 110 and a second transmission line 120 is shorted with the ground node will be described.

Referring to FIG. 6, the control unit 170 controls first and second switches SW1 and SW2, such that a differential signal is not transmitted from a transmitter Tx. For example, the control unit 170 opens the first and second switches SW1 and SW2 to disconnect the first and second transmission lines 110 and 120 from the transmitter Tx. In this case, the transmitter Tx will have a high-impedance state (Hi-Z).

The control unit 170 controls switch SWR such that a current flows into the termination resistance unit 130. For example, the control unit 170 closes the switch SWR to connect the termination resistance unit 130 to the first node N1 and the second node N2. In this case, a current flows into the termination resistance unit 130.

The control unit 170 controls a value of a first control signal CS1 such that the first pass unit 140 is turned on. That is, the control unit 170 controls the first pass unit 140 such that the first current I1 flows. Also, the control unit 170 controls a value of the second control signal CS2 such that the second pass unit 150 is turned off. That is, the control unit 170 controls the second pass unit 150 such that the second current I2 does not flow.

According to the above-described operation of the control unit 170, a condition is set up for detecting whether at least one of the first transmission line 110 and the second transmission line 120 is shorted with the ground node. Thereafter, the control unit 170 controls the measurement unit 160 to measure a voltage level of the first node N1. Whether at least one of the first transmission line 110 and the second transmission line 120 is shorted with the ground node may be detected, based on a result of measuring the voltage level of the first node N1.

A case in which the first transmission line 110 and the second transmission line 120 are not shorted with the ground node will be described with reference to FIG. 6.

Referring to FIG. 6, the first current I1 flows between one terminal and the other terminal of the first pass unit 140 according to the first control signal CS1. Because the termination resistance unit 130 is connected between the first node N1 and the second node N2, current flows between the first node N1 and the second node N2. However, a path through which the first current I1 flows is not formed because the second pass unit 150 is turned off. In this case, the voltage of the first node N1 measured by the measurement unit 160 will be approximate to the first driving voltage VDD1.

As described above, a level of the first driving voltage VDD1 is greater than a voltage level corresponding to logic high; hence, the voltage of the first node N1 may correspond to logic high. Thus, when the first transmission line 110 and the second transmission line 120 are not shorted with the ground node, the first node N1 will be measured to have a voltage level corresponding to logic high. That is, if the first node N1 has a voltage level corresponding to logic high, the measurement unit 160 will detect that the first transmission line 110 and the second transmission line 120 are not to be shorted with the ground node.

A case in which the second transmission line 120 is shorted with the ground node will be described with reference to FIG. 7.

Referring to FIG. 7, the first current I1 flows between one terminal and the other terminal of the first pass unit 140 according to the first control signal CS1. Because the termination resistance unit 130 is connected between the first node N1 and the second node N2, current flows between the first node N1 and the second node N2. Further, a path for allowing the first current I1 to flow is formed because the second node N2 is shorted with the ground node. At this time, the voltage level of the first node N1 is equal to a potential difference across the termination resistance unit 130. Accordingly, if the first current I1 is sufficiently weak, and the potential difference across the termination resistance unit 130 is smaller than a voltage level corresponding to logic low, the voltage of the first node N1 will correspond to logic low. Thus, when the second transmission line 120 is shorted with the ground node, the first node N1 will be measured to have a voltage level corresponding to logic low. That is, if the first node N1 has a voltage level corresponding to logic low, the measurement unit 160 will detect that the second transmission line 120 is shorted with the ground node.

Similarly, if the first transmission line 110 is shorted with the ground node, the first node N1 has a voltage level approximate to a ground voltage. That is, if the first transmission line 110 is shorted with the ground node, the voltage of the first node N1 will correspond to logic low. Thus, if at least one of the first transmission line 110 and the second transmission line 120 is shorted with the ground node, the first node N1 may be measured to have a voltage level corresponding to logic low. That is, if the first node N1 has a voltage level corresponding to logic low, at least one of the first transmission line 110 and the second transmission line 120 may be detected to be shorted with the ground node.

As described above, in FIGS. 6 and 7, the first current I1 should be sufficiently weak because if the first current I1 is not weak, the first node N1 does not have a voltage level corresponding to logic low when the second transmission line 120 is shorted with the ground node. Particularly, the first current I1 should be less than or equal to a value obtained by dividing a voltage level (e.g., V) corresponding to logic low by a resistance value (e.g., R) of a termination resistance unit 130, that is, I1≦V/R. The control unit 170 controls a value of the first control signal CS1 such that the first current I1 is sufficiently weak.

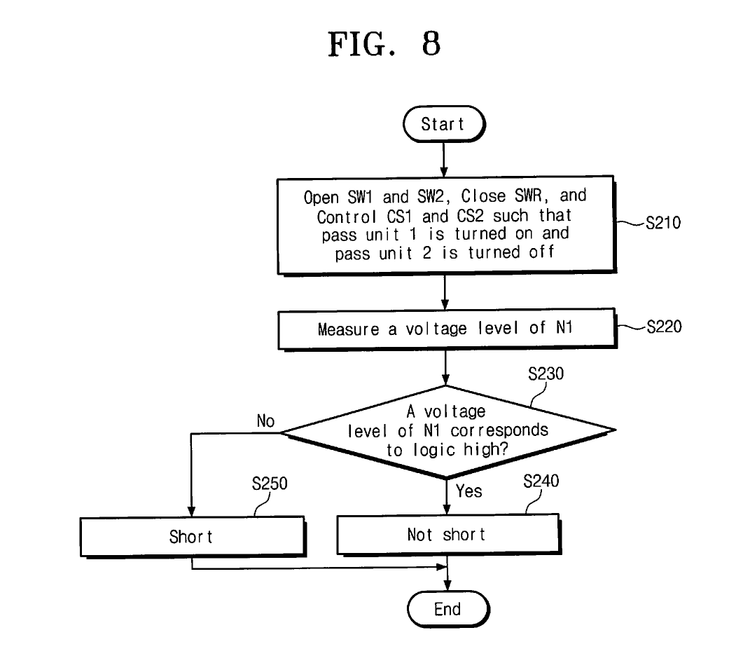

FIG. 8 is a flow chart illustrating a method of detecting whether one of differential signal transmission lines is shorted with a ground node, according to an embodiment of the present invention. Specifically, FIG. 8 illustrates an operation of detecting whether at least one of a first transmission line 110 and a second transmission line 120 of a differential signal transmission system, as illustrated in FIG. 6 or 7, is shorted with a ground node.

Referring to FIG. 8, in step S210, first and second switches SW1 and SW2 are opened, and switch SWR is closed. Also, each of values of first and second control signals CS1 and CS2 is controlled such that a first pass unit 140 is turned on and a second pass unit 150 is turned off. Basically, a condition is set for detecting whether at least one of a first transmission line 110 and a second transmission line 120 is shorted with the ground node in step S210.

In step S220, a voltage level of a first node N1 is measured. Whether at least one of the first transmission line 110 and the second transmission line 120 is shorted with the ground node is determined based on a result of measuring the voltage level of the first node N1.

In step S230, if the voltage level of the first node N1 corresponds to logic high, it is determined that the first transmission line 110 and the second transmission line 120 are not shorted with the ground node in step S240. However, if the voltage level of the first node N1 does not correspond to logic high (corresponds to logic low) in step S230, it is determined that at least one of the first transmission line 110 and the second transmission line 120 is shorted with the ground node in step S250.

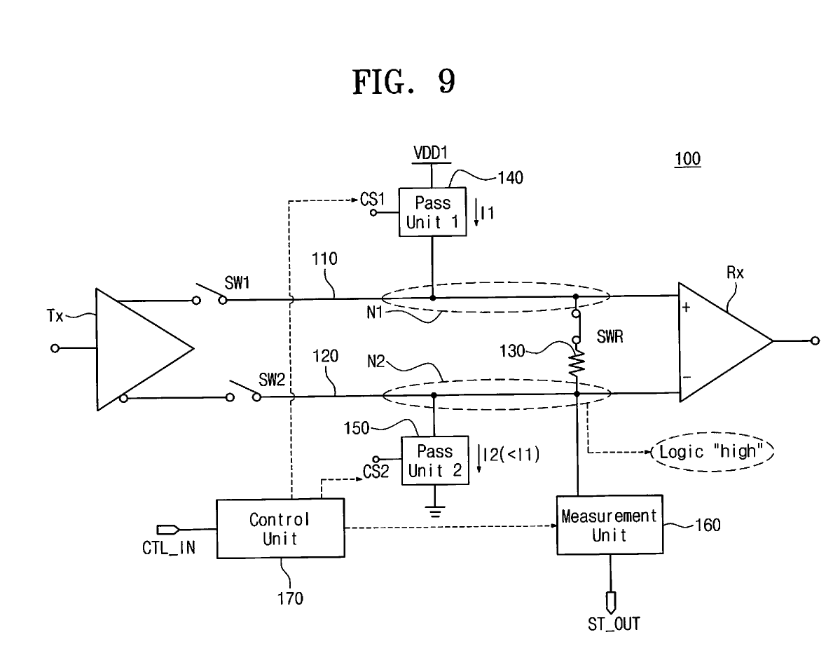

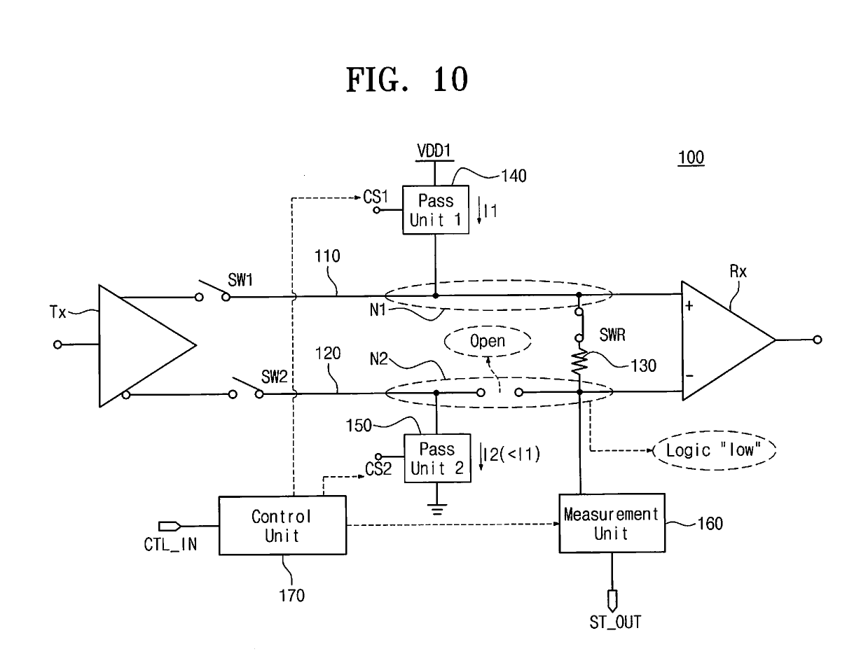

FIGS. 9 and 10 illustrate an operation of detecting whether one of differential signal transmission lines is opened, according to an embodiment of the present invention. As described above, it is assumed that a first driving voltage VDD1 is a positive voltage having a level greater than a voltage level corresponding to logic high and a second driving voltage VDD2 is a ground voltage.

First, an operation of setting a condition for detecting whether at least one of a first transmission line 110 and a second transmission line 120 is opened will be described.

Referring to FIG. 9, the control unit 170 controls first and second switches SW1 and SW2 such that a differential signal is not transmitted from a transmitter Tx. For example, the control unit 170 opens the first and second switches SW1 and SW2 to disconnect the first and second transmission lines 110 and 120 from the transmitter Tx. In this case, the transmitter Tx will have a high-impedance state (Hi-Z).

The control unit 170 controls switch SWR such that a current flows into the termination resistance unit 130. For example, the control unit 170 closes the switch SWR to connect the termination resistance unit 130 to the first node N1 and the second node N2. In this case, a current flows into the termination resistance unit 130.

The control unit 170 controls each of values of first and second control signals CS1 and CS2 such that first and second pass units 140 and 150 are turned on. That is, the control unit 170 controls the first and second pass units 140 and 150 such that a first current I1 and a second current I2 flow. Also, the control unit 170 controls each of the values of the first and second control signals CS1 and CS2 such that the first current I1 is greater than the second current I2.

According to the above-described operation of the control unit 170, a condition is set up for detecting whether at least one of the first transmission line 110 and the second transmission line 120 is opened. Thereafter, the control unit 170 controls the measurement unit 160 to measure a voltage level of the second node N2. Whether at least one of the first transmission line 110 and the second transmission line 120 is opened may be determined, based on a result of measuring the voltage level of the second node N2.

A case in which the first transmission line 110 and the second transmission line 120 are not opened will be described with reference to FIG. 9.

Referring to FIG. 9, the first current I1 flows between one terminal and the other terminal of the first pass unit 140, based on the first control signal CS1. Current also flows between the first node N1 and the second node N2 because the termination resistance unit 130 is connected between the first node N1 and the second node N2. The second current I2 flows between one terminal and the other terminal of the second pass unit 150, based on the second control signal CS2. Because the first current I1 is greater than the second current I2 (i.e., a driving power of the first pass unit 140 is greater than that of the second pass unit 150), a voltage of the second node N2 measured by the measurement unit 160 has a voltage level approximate to the first driving voltage VDD1. That is, the second node N2 may be measured to have a voltage level corresponding to logic high. As a result, when the first transmission line 110 and the second transmission line 120 are not opened, the voltage level of the second node N2 will correspond to logic high. That is, if the second node N2 has a voltage level corresponding to logic high, the first transmission line 110 and the measurement unit 160 will detect that the second transmission line 120 is not opened.

A case in which the second transmission line 120 is opened will be described with reference to FIG. 10.

Referring to FIG. 10, the first current I1 flows between one terminal and the other terminal of the first pass unit 140 according to the first control signal CS1, and the second current I2 flows between one terminal and the other terminal of the second pass unit 150 according to the second control signal CS2. However, because the second transmission line 120 is opened, a path for the current to flow between the other terminal of the first pass unit 140 and one terminal of the second pass unit 150 is not formed. In this case, a voltage of the second node N2 measured by the measurement unit 160 will be approximate to the ground voltage. That is, the second node N2 will be measured to have a voltage level corresponding to logic low. As a result, when the second transmission line 120 is opened, the voltage level of the second node N2 will correspond to logic low. That is, if the second node N2 has a voltage level corresponding to logic low, the measurement unit 160 will detect the second transmission line 120 to be opened.

Similarly, when the first transmission line 110 is opened, a path for current to flow between the other terminal of the first pass unit 140 and one terminal of the second pass unit 150 is not formed. In this case, the second node N2 has a voltage level approximate to a ground voltage. That is, if the first transmission line 110 is opened, the second node N2 has a voltage level corresponding to logic low. Thus, the voltage level of the second node N2 will correspond to logic low when at least one of the first transmission line 110 and the second transmission line 120 is opened. That is, if the second node N2 has a voltage level corresponding to logic low, the measurement unit 160 will detect that at least one of the first transmission line 110 and the second transmission line 120 is opened.

In FIGS. 9 and 10, a driving power of the first pass unit 140 is greater than that of the second pass unit 150. That is, the first current I1 is greater than the second current I2. If the first current I1 is insufficient, a voltage level of the second node N2 measured when the first transmission line 110 and the second transmission line 120 are not opened may not correspond to logic high. However, the excessive first current I1 may cause an unstable operation and high power consumption of the differential signal transmission system 100. In accordance with an embodiment of the present invention, the control unit 170 adjusts each of values of the first and second control signals CS1 and CS2 such that the first current I1 is four times greater than the second current I2.

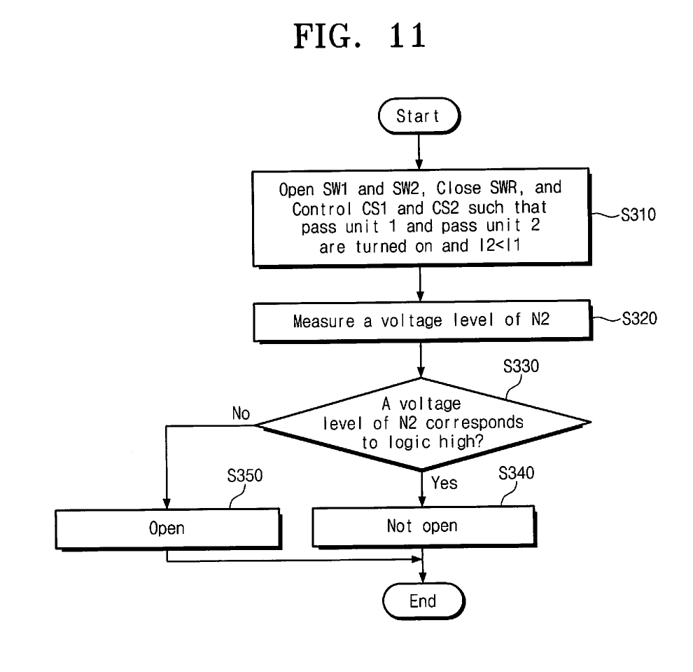

FIG. 11 is a flow chart illustrating a method of detecting whether one of differential signal transmission lines is opened, according to an embodiment of the present invention. Specifically, FIG. 11 illustrates an operation of detecting whether at least one of the first transmission line 110 and the second transmission line 120 of a differential signal transmission system, as shown in FIG. 9 or 10, is opened.

Referring to FIG. 11, in step S310, first and second switches SW1 and SW2 are opened, and switch SWR is closed. Each value of the first and second control signals CS1 and CS2 is controlled such that the first pass unit 140 and the second pass unit 150 are turned on and that the second current I2 and the first current I1, which is stronger than the second current I2, flow. Basically, in step S310, a condition is set for detecting whether at least one of the first transmission line 110 and the second transmission line 120 is opened.

In step S320, a voltage level of the second node N2 is measured. Whether at least one of the first transmission line 110 and the second transmission line 120 is opened is determined based on a result of measuring the voltage level of the second node N2.

In step S330, if the voltage level of the second node N2 corresponds to logic high, it is determined that the first transmission line 110 and the second transmission line 120 are not opened in step S340. However, if the voltage level of the second node N2 does not correspond to logic high (corresponds to logic low), it is determined that at least one of the first transmission line 110 and the second transmission line 120 is opened in step S350.

In accordance with the above-described embodiments of the present invention, it is possible to quickly and easily detect a faulty state of the first transmission line 110 and the second transmission line 120. In particular, a faulty state of the first transmission line 110 and the second transmission line 120 may be automatically detected based on an embedded instruction of a differential signal transmission system 100. Thus, it is possible to markedly reduce a time for development and debugging. That is, detection of a faulty state of the first transmission line 110 and the second transmission line 120 may be made economically and efficiently in terms of time and cost.

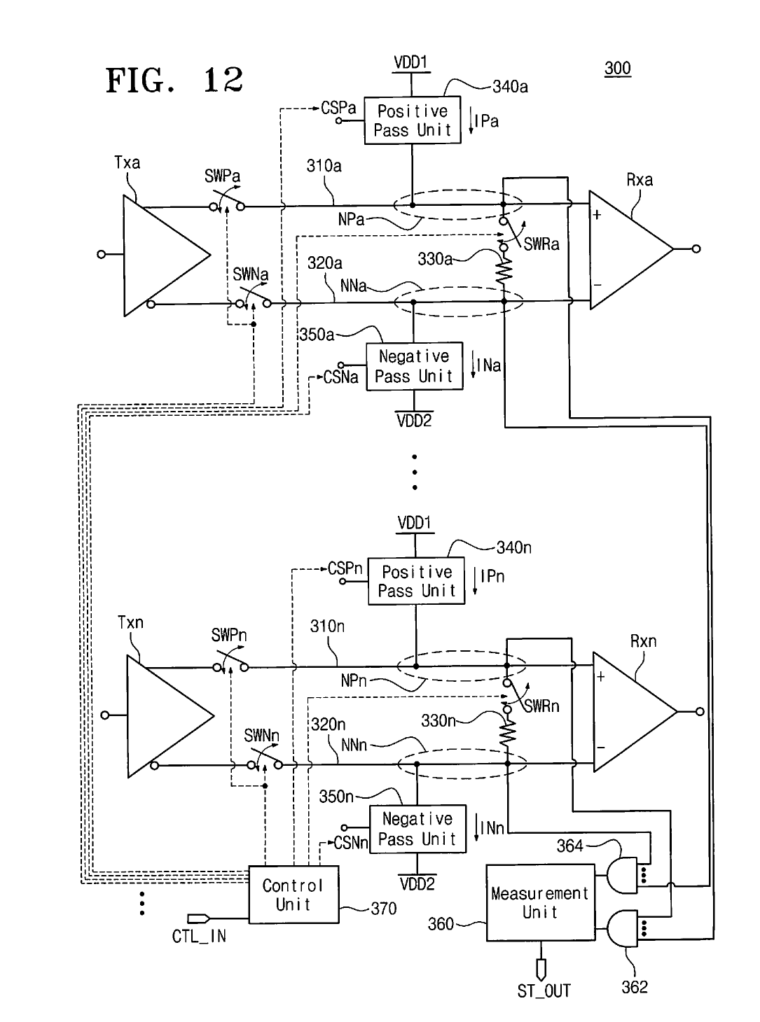

FIG. 12 schematically illustrates a differential signal transmission system according to an embodiment of the present invention.

Referring to FIG. 12, the differential signal transmission system 300 includes a plurality of differential signal line pairs 310a and 320a to 310n and 320n, a plurality of termination resistance units 330a to 330n, a plurality of positive pass units 340a to 340n, a plurality of negative pass units 350a to 350n, a measurement unit 360, and a control unit 370.

Functions and configurations of the differential signal line pairs 310a and 320a to 310n and 320n, termination resistance units 330a to 330n, positive pass units 340a to 340n, and negative pass units 350a to 350n are similar to the functions and configurations of differential signal line pairs including the first transmission line 110 and the second transmission line 120, the termination resistance unit 130, the first pass unit 140, and the second pass unit 150 of the differential signal transmission system 100 as illustrated in FIG. 1. Also, functions and configurations of the measurement unit 160 and the control unit 170 of the differential signal transmission system 100 are similar to the measurement unit 360 and the control unit 370, as illustrated in FIG. 12. Therefore, a repetitive description of the differential signal line pairs 310a and 320a to 310n and 320n, termination resistance units 330a to 330n, positive pass units 340a to 340n, negative pass units 350a to 350n, measurement unit 360, and control unit 370 is omitted herein.

Each of the differential signal line pairs 310a and 320a to 310n and 320n may transmit a differential signal. The differential signal line pairs 310a and 320a to 310n and 320n may include positive channels 310a to 310n and negative channels 320a to 320n, respectively. If positive channel switches SWPa to SWPn are closed, the positive channels 310a to 310n are connected to transmitters Txa to Txn, respectively. If negative channel switches SWNa to SWNn are closed, the negative channels 320a to 320n are connected to the transmitters Txa to Txn, respectively.

The termination resistance units 330a to 330n are connected between positive nodes NPa to NPn on the positive channels 310a to 310n and negative nodes NNa to NNn on the negative channels 320a to 320n, respectively. If switches SWRa to SWRn are closed, the termination resistance units 330a to 330n are connected with the positive nodes NPa to NPn and the negative nodes NNa to NNn, respectively.

Each one of the terminals of the positive pass units 340a to 340n are connected to a first driving voltage VDD1, and each of the other terminals thereof are connected to the positive nodes NPa to NPn, respectively. Positive currents IPa to IPn flowing through the positive pass units 340a to 340n may be controlled according to positive control signals CSPa to CSPn corresponding to the positive pass units 340a to 340n, respectively. Each one of the terminals of the positive pass units 340a to 340n may be provided with the first driving voltage VDD1 from the same or different voltage sources. The positive pass units 340a to 340n may be provided with the same or different positive control signals CSPa to CSPn.

Each one of the terminals of the negative pass units 350a to 350n are connected to the negative nodes NNa to NNn, respectively. Each of the other terminals of the negative pass units 350a to 350n are connected to a second driving voltage VDD2, which may have a level lower than a level of the first driving voltage VDD1. Negative currents INa to INn flowing through the negative pass units 350a to 350n may be controlled according to negative control signals CSNa to CSNn corresponding to the negative pass units 350a to 350n, respectively. Each one of the terminals of the negative pass units 350a to 350n may be provided with the second driving voltage VDD2 from the same or different voltage sources. The negative pass units 350a to 350n may be provided with the same or different negative control signals CSNa to CSNn.

The measurement unit 360 measures a voltage level of at least one of the positive nodes NPa to NPn and the negative nodes NNa to NNn. In accordance with an embodiment of the present invention, the positive nodes NPa to NPn are connected to input terminal of the same logic circuit 362. The negative nodes NNa to NNn are connected to input terminal of the same logic circuit 364. The measurement unit 360 is provided with results of logical operations of the logic circuits 362 and 364.

For example, the logic circuit 362 performs an AND operation. When each of the positive nodes NPa to NPn has a voltage level corresponding to logic high, the logic circuit 362 outputs a voltage level corresponding to logic high to the measurement unit 360. However, if at least one of the positive nodes NPa to NPn has a voltage level corresponding to logic low, the logic circuit 362 outputs a voltage level corresponding to logic low to the measurement unit 360. The measurement unit 360 detects faulty states of the positive channels 310a to 310n and the negative channels 320a to 320n, based on outputs of the logic circuit 362.

For example, the logic circuit 364 performs an AND operation. When each of the negative nodes NNa to NNn has a voltage level corresponding to logic high, the logic circuit 364 outputs a voltage level corresponding to logic high to the measurement unit 360. However, if at least one of the negative nodes NNa to NNn has a voltage level corresponding to logic low, the logic circuit 364 outputs a voltage level corresponding to logic low to the measurement unit 360. The measurement unit 360 detects faulty states of the positive channels 310a to 310n and the negative channels 320a to 320n, based on outputs of the logic circuit 364.

With the differential signal transmission system illustrated in FIG. 12, it is possible to measure voltage levels of all positive and negative nodes NPa to NPn and NNa to NNn by using one measurement unit 360. However, the present invention is not limited thereto. For example, voltage levels of positive and negative nodes NPa to NPn and NNa to NNn may be measured using different measurement units. Further, the logic circuits 362 and 364 may be disposed inside of the measurement unit 360. Alternatively, the measurement unit 360 may be configured to receive voltages of all the positive and negative nodes NPa to NPn and NNa to NNn directly without using the logic circuits 362 and 364.

The control unit 370 controls components and signals of the differential signal transmission system 300. The control unit 370 controls the positive channels switches SWPa to SWPn and the negative channel switches SWNa to SWNn to control a transfer of a differential signal. The control unit 370 controls the switches SWRa to SWRn for controlling connections of the termination resistance units 330a to 330n. Also, the control unit 370 adjusts each of values of the positive and negative control signals CSPa to CSPn and CSNa to CSNn to control the positive and negative currents IPa to IPn and INa to INn.

All components and signals of the differential signal transmission system 300 may be controlled by one control unit 370. However, the present invention is not limited thereto. For example, components and signals of the differential signal transmission system 300 may be controlled by different control units.

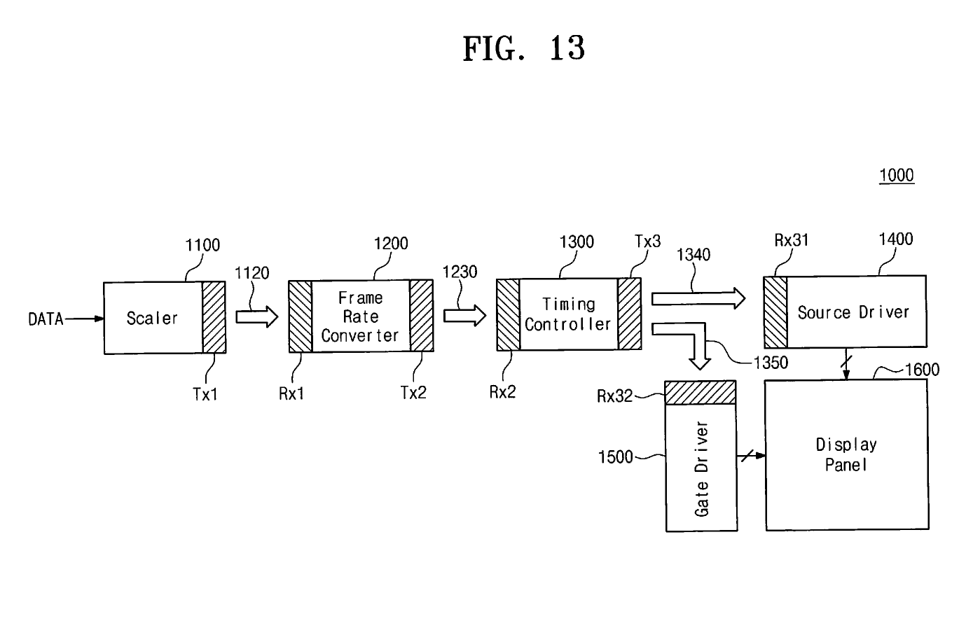

FIG. 13 is a block diagram illustrating a display device including a differential signal interface according to an embodiment of the present invention.

Referring to FIG. 13, the display device 1000 includes a scaler 1100, a frame rate converter 1200, a timing controller 1300, a source driver 1400, a gate driver 1500, and a display panel 1600. The display device 1000 further includes differential signal interfaces 1120, 1230, 1340, and 1350 for a signal transfer between the various components.

The scaler 1100 is provided with data (DATA) including images to be displayed on the display panel 1600 and image information. The scaler 1100 processes the data to allow the data to have resolution information suitable for an image to be displayed on the display panel 1600. The data processed by the scaler 1100 is provided to the frame rate converter 1200 via the differential signal interface 1120. The differential signal interface 1120 transmits a signal, corresponding to the data, from a transmitter Tx1 to a receiver Rx1. For example, the differential signal interface 1120 may be an LVDS interface. In particular, the differential signal interface 1120 may be implemented according to the embodiments of the invention described above. Accordingly, a faulty state of differential signal transmission lines included in the differential signal interface 1120 may be detected easily within a short time according to an embodiment of the present invention.

The frame rate converter 1200 processes data corresponding to the transmitted signal to adjust frequency (i.e., a frame rate) by which a frame is displayed on the display panel 1600. The data processed by the frame rate converter 1200 is provided to the timing controller 1300 via the differential signal interface 1230. The differential signal interface 1230 transmits a signal, corresponding to the processed data, from a transmitter Tx2 to a receiver Rx2. For example, the differential signal interface 1230 may be an LVDS interface. In particular, the differential signal interface 1230 may be implemented according to the embodiments of the invention described above. Accordingly, a faulty state of differential signal transmission lines included in the differential signal interface 1230 may be detected easily within a short time according to an embodiment of the present invention.

The timing controller 1300 distributes the data into the source driver 1400 and the gate driver 1500 to control an image output of the display panel 1600. In particular, the timing controller 1300 is configured to prevent occurrence of time difference from an image output in a large-sized display device. The timing controller 1300 distributes the data into the source driver 1400 and the gate driver 1500 via the differential signal interface 1340 and the differential signal interface 1350, respectively. The differential signal interface 1340 is configured to transmit a signal between a transmitter Tx3 and a receiver Rx31, and the differential signal interface 1350 is configured to transmit a signal between the transmitter Tx3 and a receiver Rx32. For example, the differential signal interfaces 1340 and 1350 may be a mini-LVDS interface or an AIPI. In particular, the differential signal interfaces 1340 and 1350 may be implemented according to the embodiments of the invention described above. Accordingly, faulty states of differential signal transmission lines included in the differential signal interfaces 1340 and 1350 may be detected easily within a short time according to an embodiment of the present invention.

The source driver 1400 and the gate driver 1500 provide signals to the display panel 1600 such that an image is properly displayed in each pixel of the display panel 1600. The display panel 1600 displays an image based on received signals.

The display device 1000 may also be configured to include other components or not to include one or more components illustrated in FIG. 13. Further, a differential signal transmission system according to an embodiment of the present invention is applicable to a device or system different from the display device 1000. That is, the differential signal transmission system according to an embodiment of the present invention is applicable to any device or system including an interface using a differential signal.

Device components illustrated in each block diagram are provided for better understanding of the inventive concept. Each block may be formed of smaller blocks according to functionality. Further, a plurality of blocks may constitute a larger block according to functionality. That is, the present invention is not limited to components illustrated in each diagram.

While the present invention has been described with reference to certain embodiments thereof, it will be apparent to those skilled in the art that various changes and modifications may be made without departing from the spirit and scope of the present invention as defined by the appended claims and any equivalents thereof.

What is claimed is:

1. A differential signal transmission system comprising:
a first transmission line and a second transmission line configured to transmit a differential signal;
a termination resistance unit connected between a first node on the first transmission line and a second node on the second transmission line;
a first pass unit configured to control a first current flowing between a third node connected to a first driving voltage and the first node based on a first control signal;
a second pass unit configured to control a second current flowing between the second node and a fourth node connected to a second driving voltage based on a second control signal, wherein a level of the second driving voltage is lower than a level of the first driving voltage;
a measurement unit configured to measure a voltage level of at least one of the first node and the second node to detect an open or short state of at least one of the first transmission line and the second transmission line; and
a control unit configured to control at least one of a transmission of the differential signal, a connection of the termination resistance unit, a value of the first control signal, and a value of the second control signal.

2. The differential signal transmission system of claim 1, wherein the first pass unit comprises a P-channel Metal-Oxide Semiconductor (PMOS) transistor and the second pass unit comprises an N-channel Metal-Oxide Semiconductor (NMOS) transistor.

3. The differential signal transmission system of claim 1, wherein the control unit is further configured to control the differential signal not to be transmitted, to control the termination resistance unit not to be connected to at least one of the first node and the second node, and to control the value of the first control signal and the value of the second control signal such that the first pass unit and the second pass unit are turned on and the second current is greater than the first current.

4. The differential signal transmission system of claim 3, wherein the control unit is further configured to control the measurement unit to measure the voltage level of the first node.

5. The differential signal transmission system of claim 4, wherein the first transmission line is determined to be shorted with the second transmission line when a measured voltage of the first node corresponds to logic low, and
wherein the first transmission line is determined not to be shorted with the second transmission line when the measured voltage of the first node corresponds to logic high.

6. The differential signal transmission system of claim 3, wherein the control unit is further configured to adjust the value of the first control signal and the value of the second control signal such that the second current is four times greater than the first current.

7. The differential signal transmission system of claim 1, wherein the control unit is further configured to control the differential signal not to be transmitted, to control the termination resistance unit to be connected to the first node and the second node, to control the value of the first control signal such that the first pass unit is turned on, and to control the value of the second control signal such that the second pass unit is turned off.

8. The differential signal transmission system of claim 7, wherein the control unit is further configured to control the measurement unit to measure the voltage level of the first node.

9. The differential signal transmission system of claim 8, wherein at least one of the first transmission line and the second transmission line is determined to be shorted with a ground node when a measured voltage of the first node corresponds to logic low, and
wherein the first transmission line and the second transmission line are determined not to be shorted with the ground node when the measured voltage of the first node corresponds to logic high.

10. The differential signal transmission system of claim 7, wherein the control unit is further configured to control the first current such that a value of the first current is less than or equal to a value obtained by dividing a voltage level corresponding to logic low by a resistance value of the termination resistance unit.

11. The differential signal transmission system of claim 1, wherein the control unit is further configured to control the differential signal not to be transmitted, to control the termination resistance unit to be connected to the first node and the second node, and to control a value of the first control signal and a value of the second control signal such that the first pass unit and the second pass unit are turned on and the first current is greater than the second current.

12. The differential signal transmission system of claim 11, wherein the control unit is further configured to control the measurement unit to measure the voltage level of the second node.

13. The differential signal transmission system of claim 12, wherein at least one of the first transmission line and the second transmission line is determined to be opened when a measured voltage of the second node corresponds to logic low, and
wherein the first transmission line and the second transmission line are determined not to be opened when the measured voltage of the second node corresponds to logic high.

14. The differential signal transmission system of claim 11, wherein the control unit is further configured to adjust the value of the first control signal and the value of the second control signal such that the first current is four times greater than the second current.

15. A differential signal transmission system comprising:
a plurality of differential signal line pairs, each of the plurality of differential signal line pairs including a positive channel and a negative channel configured to transfer a differential signal;
a plurality of termination resistance units, each of the plurality of termination resistance units being connected between a positive node on a respective positive channel and a negative node on a respective negative channel;
a plurality of positive pass units, each of the plurality of positive pass units configured to control a positive current flowing between a first node connected to a first driving voltage and a respective positive node based on a positive control signal;
a plurality of negative pass units, each of the plurality of negative pass units configured to control a negative current flowing between a respective negative node and a second node connected to a second driving voltage based on a negative control signal, wherein a level of the second driving voltage is lower than a level of the first driving voltage;
a measurement unit configured to measure a voltage level of at least one of the positive nodes and the negative nodes to detect an open or short state of each of the plurality of differential signal line pairs; and
a control unit configured to control at least one of a transfer of the differential signal, a connection of each of the plurality of termination resistance units, a value of the positive control signal, and a value of the negative control signal.

16. A method of detecting an open state or a short state of at least one of a first transmission line and a second transmission line of a differential signal transmission system, the method comprising:
controlling a first current flowing between a third node connected to a first driving voltage and a first node on the first transmission line based on a first control signal;
controlling a second current flowing between a second node on the second transmission line and a fourth node connected to a second driving voltage based on a second control signal, wherein a level of the second driving voltage is lower than a level of the first driving voltage;
measuring a voltage level of at least one of the first node and the second node; and
detecting the open state or the short state of the at least one of the first transmission line and the second transmission line, based on the measured voltage level.

17. The method of claim 16, wherein measuring the voltage level of the at least one of the first node and the second node comprises measuring the voltage level of the first node.

18. The method of claim 17, wherein detecting the open state or the short state of the at least one of the first transmission line and the second transmission line, based on the measured voltage level comprises:
determining that the first transmission line is shorted with the second transmission line, when the measured voltage of the first node corresponds to logic low; and
determining that the first transmission line is not shorted with the second transmission line, when the measured voltage of the first node corresponds to logic high.

19. The method of claim 17, wherein detecting the open state or the short state of the at least one of the first transmission line and the second transmission line, based on the measured voltage level comprises:
determining that the at least one of the first transmission line and the second transmission line is shorted with a ground node, when the measured voltage of the first node corresponds to logic low, and
determining that first transmission line and the second transmission line are not shorted with the ground node, when the measured voltage of the first node corresponds to logic high.

20. The method of claim 16, wherein measuring the voltage level of the at least one of the first node and the second node comprises measuring the voltage level of the second node, and
wherein detecting the open state or the short state of the at least one of the first transmission line and the second transmission line, based on the measured voltage level comprises:
determining that at least one of the first transmission line and the second transmission line is opened, when the measured voltage of the second node corresponds to logic low, and
determining that the first transmission line and the second transmission line are not opened, when the measured voltage of the second node corresponds to logic high.
